(19) United States
(12) Patent Application Publication
(10) Pub. No.: US 2021/0293906 A1
(43) Pub. Date: Sep. 23, 2021

(54) Method for Detecting Common Mode and Other Interfering Magnetic Fields

(71) Applicant: Methode Electronics Malta Ltd., Birkirkara (MT)

(72) Inventor: Ignazio Barraco, München (DE)

(21) Appl. No.: 17/207,842

(22) Filed: Mar. 22, 2021

(30) Foreign Application Priority Data
Mar. 23, 2020 (DE) 10 2020 107 889.7

(51) Int. Cl. G01R 33/09; G01R 33/00

(52) U.S. Cl. CPC G01R 33/09; G01R 33/0011

(57) ABSTRACT

A method detects a proportion of a common mode magnetic field transmitted together with a signal magnetic field each emitted by one of at least two magnetic field sensors (S1; S2), wherein the magnetic field sensors (S1; S2) are connected in at least one electric circuit, and at least two differential drive clocks (A; B) reverse the current flowing in the electric circuit.

### CROSS-REFERENCE TO RELATED APPLICATIONS

This application claims the benefit of German Application DE 10 2020 107 889.7, filed Mar. 23, 2020, which is incorporated by reference herein in its entirety.

### BACKGROUND OF THE INVENTION

The invention refers to a method for detecting common mode and other interfering magnetic fields.

The document U.S. Pat. No. 8,893,562 B2 reveals a torque sensing device for measuring the torque applied to a rotatable shaft, and also for measuring the magnetic field noise affecting the device. The device incorporates a switching function thereby enabling the device to operate in a common signal detection mode and a differential noise detection mode.

Conventionally the sensors known in the state-of-the-art measure very small differential magnetic fields.

Said magnetic field is associated with a stress acting on a piece of metal.

It goes without saying that the stress can also be a shear force where the stress is brought into the material.

In traditional sensors these measurements can be influenced by external magnetic fields, thus causing inaccuracies.

In the past, the presence of external magnetic fields was detected by further sensors, additionally implemented into the system.

The further sensors were used for diagnostic purposes. The further sensors, used in the state-of-the-art were installed to prevent sensors from being less accurate. The inaccuracy was due to external magnetic fields.

Implementing further, additional sensors turned out to be very costly and expensive, because a number of further channels is needed.

In reality however the fields passing through these further sensors were not equal all the time.

Furthermore, these fields are diverging fields. The reason being that the external magnetic stray fields or that near fields do not always pass through the sensors either directed in the same manner or in the same intensity.

In reality, however, the common mode field terms do not disappear. In other words, the common mode currents cm1 and cm2, do not always disappear.

To correct the measurement, a measurement current (ic) is implied, which is the correction current ic into the Ct node, which again is the difference between the sensor signal and the common mode fields.

Thus, measurements are often incorrect. The error in the measurement is based on difference of the external fields, measured by the sensors S1 and S2.

Also, the external field measured by the sensor S1 could be bigger or smaller relative to the external field measured by the sensor S2.

This is to demonstrate, that the current ic in a direction to or from the Ct node remain in the same direction for any given signal. In this specific example, this is how the sensor of the state-of-the-art works.

### Problem

When using a bipolar magnetometer with different drive voltages a magnetic field detection and at least one correction point has been discovered to show disturbances in the behaviour of the circulating currents.

Said circulating currents are associated with the drive characteristics and the presence of both wanted signal fields and unwanted common mode fields and/or external interfering magnetic fields.

Conventionally this problem has been addressed by implementing further, additional sensors or other channels respectively.

### Purpose of the Invention

It is the object of the invention to address the deficiencies of the methods, known in the state-of-the-art.

Reference is made to the FIG. 1 and FIG. 2.

During the phase 1 and/or when the drive clock A is set high (5 V) there is a current i1 towards the centre tap (CT) and a current i2, after the tap (CT). The (CT) is positioned between the sensors S1 and S2.

It is one purpose of the invention to determine the part of the signal of the sensor S1 made up of the common mode signal.

Also, it is one further purpose of the invention to determine the part of the signal of the sensor S2, made up of the common mode signal.

Said voltage value, representing the current showing the common mode signal within the signal of sensor S1 is represented by the signal A+.

Also, the voltage value, representing the current showing the common mode signal within the signal of the sensor S2 is represented by the signal B+.

The signal ic represents the difference between the current of the sensor ic and the current of the common mode field icm.

In other words, it's the intention of the invention to determine, to which extent the signal of the sensor S1 and/or signal of the sensor S2 is made up of an external magnetic field.

Thus, it is the intention of the invention to determine how much of interfering field is present in the signal of the sensor S1 and/or in the signal of the sensor S2.

### Sensors and Channels

The sensor in the sense of the present invention is a magnetic field sensor. According to the invention there is at least one sensor for measuring a torque applied to a magnetoelastic body and for simultaneously detecting a potential external magnetic field.

Said sensor comprises at least one first principle and one second principle. The principle of the sensor is the relevant one for measuring the effect of torque applied to the magnetoelastic body. To some extent the principal detects an effect of an external magnetic field to the magnetoelastic sensor. The principal of the sensor only detects the effect of the external magnetic field to the magnetoelastic body. The principal does not measure any torque applied to the magnetoelastic body.

In the present invention, the sensor is applied as a flux gate sensor.

It goes without saying that the sensor is also referred to as sensing element. There can be any number of sensors and/or channels applied to the system.

By means of example, the system comprises one single channel. It goes without saying that any number of channels can be applied.

In the following the patent application only refers to magnetic field sensors.

### Solution by the Invention

In the following, reference is made to the formulas listed below. Also, reference is made to the FIGS. 6 and 7.

The present invention refers to the term torque as a force applied onto an object that creates stress in the object such as a magneto-elastic body.

The present application uses the expressions torque and stress as synonyms.

By analysing a behaviour of at least one circulating current the wanted signal magnetic fields can be distinguished from the unwanted common mode fields and or from nearby magnetic fields.

According to the invention the information regarding the presence and the strength of the interfering magnetic fields are used as a diagnostic for purposes of additional information on the handling of the sensor signals during the presence of the interfering signals.

The information regarding the presence and the strength of the interfering magnetic fields can be used as a calibrated threshold value and out of tolerance diagnostic.

The information regarding the presence and strength of the interfering magnetic fields can also be used as a correction method for reducing the negative effects, so that the sensor remains within its desired specifications.

To detect how much interfering field is present in the signal of the sensor S1 and/or the sensor S2.

The current flowing into the system is called (i1). The current of the sensor S1, comprising both the S1 signal and part representing the common mode field is called A+.

The signal issued by the sensor S1 and/or S2 is always the difference between the signal of the sensor disturbed by the common mode field. Thus, the signal issued by the sensor S1 and/or S2 is the current ic.

However, one never knows what the value of the current of the sensor S1 or S2 is, relative to the value of the common mode field (icm).

Thus, the object of the invention is to detect what the exact value is of both the signal of the sensor (is1 or is2) and the value of the common mode field (icm1; icm2).

The current flowing out of the CT, is represented by B minus (B−).

Thus, the current flowing out of the CT is made up of the signal of the sensor (is2) minus the current of the common mode interfering with the sensor S2 (icm2).

In the FIG. 7 the system is shown the other way round, with the drive clock A shifting from 5V to 0V, whereas the drive clock B shifts from 0 V to 5 V.

Thus, the invention allows to identify the common mode fields, which would usually disappear in the measurements.

It is one advantage of the invention that a plurality of sensors become redundant, as there is no sensor exclusively necessary to detect the external field only.

According to the invention, the presence of the common mode field and/or the presence of the interfering field can be detected within one single magnetic field sensor of a channel.

Thus, according to the invention, one knows what the signal of the sensor is and also the interfering field becomes visible.

According to the invention (especially, FIG. 6 and FIG. 7) the value of A+ is measured, showing the positive current flowing through the sensor S1.

The value B− however, representing the negatives current, flowing into the B channel, where the drive clock B is low. In the situation as shown, where the drive clock A is high and the drive clock B is low.

Thus, in phase 2, B+ shows the current flowing from the drive clock B towards the centre tap (CT).

The value A− represents the current flowing from the centre tap (CT), when the drive clock A is low.

Now, the invention combines these measurements to extract the amount of interfering field.

The interfering field is called IFD.

The invention introduces resistors (R1; R2), which are placed symmetrically across the centre tap (CT).

In phase 1 the A+ represents the measurement point next to R1. B− however is the measurement point after R2.

The terms A+ and B− refer to a situation in phase 1, when the currents flow from drive clock A to drive clock B.

The R1 and the R2 are resistors. It is the task of the resistors R1 and R2 to convert the currents into a voltage.

Resistors R1 and R2 are introduced into the system, because the magnitudes of the currents i1 and i2 of the sensors S1 and S2 are measured.

The magnitudes of the currents i1 and i2 are measured in two different phases.

Each sensor S1 and S2 is allocated one resistor R1 and R2, respectively. The reason being, the sensors S1 and S2 are part of a so-called bridge. The bridge on either side of the centre tap (CT) has to be balanced.

Whatever is done on one half of the bridge in the area of the sensor S1 or the sensor S2 has to be done on the other half of the bridge (sensor S2 or sensor S1) as well.

If only one resistor (R1; R2) is introduced on one half of the bridge, an offset would be created in the system.

Alternatively, it would cause a nonlinearity in the system.

### BRIEF DESCRIPTION OF THE DRAWINGS

FIG. 1 shows a drive clock A and an opposite drive clock B with varying polarities.

FIG. 2 shows a drive clock A and an opposite drive clock B with polarities varying relative to FIG. 1.

FIG. 3 shows a drive clock A and an opposite drive clock B with common mode interfering magnetic fields.

FIG. 4 shows the electric circuit comprising a centre tap (CT).

FIG. 5 shows the electric circuit comprising a centre tap (CT), with the electric current flowing in the opposite direction relative to FIG. 4.

FIG. 6 shows the electric circuit comprising a resistor.

FIG. 7 shows the electric circuit comprising a resistor, with the electric current flowing in the opposite direction relative to FIG. 6.

Reference numerals in the written specification and in the figures indicate corresponding items.

### DETAILED DESCRIPTION

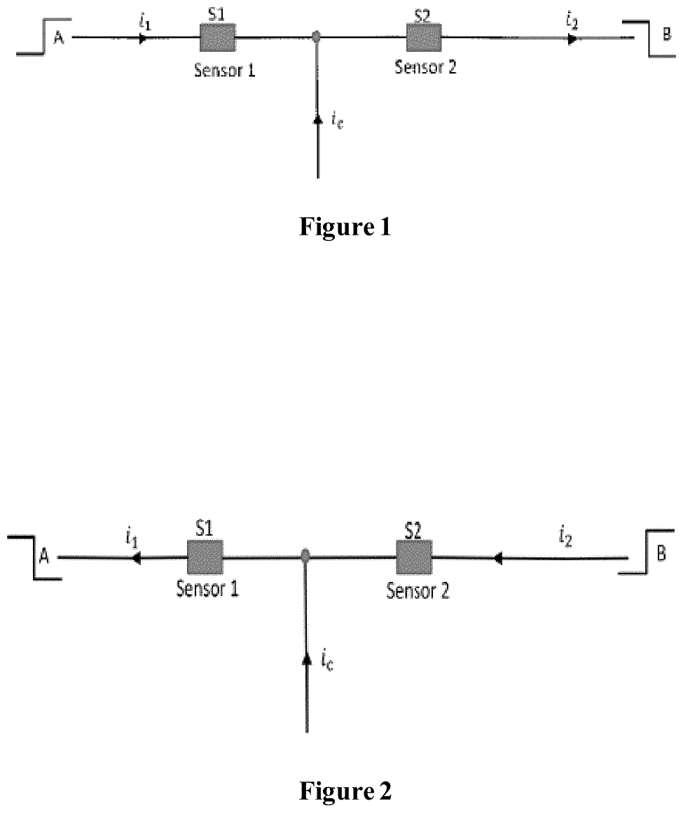

According to the FIG. 1 and FIG. 2, magnetic field sensors S1 and S2 are arranged in a current circuit. Any type of magnetic field sensors can be used for the sensors S1 and S2.

Said sensors S1 and S2 are measuring fields in opposite directions. To operate a flux gate sensor, according to the invention, a frequency has to be set which can also be addressed to as a drive clock frequency with a preset value usually in the 10's of kilohertz (KHz) range depending on the number and characteristics of the flux gates.

In a given phase 1 a drive clock A is high and an opposite drive clock B is low.

Whereas in a given phase 2, drive polarities are switched, so that a drive clock B is high and the drive clock A is low.

For this reason, the currents between said sensor S1 and the sensor S2 move backwards and forwards.

In a given phase 1, the current moves from drive clock A to drive clock B, whereas in a given phase 2, the current moves from B to A.

The term clock is referred to as a 5 V (Volt) digital clock. Thus, the voltage can be changed from 0 V to 5 V and the other way round. It goes without saying that different voltage values can be applied as well. This principle can also work with a single ended drive clock.

Thus, the currents move backward and forward through the sensing network, formed by the sensors S1 and S2. In other words, the currents moving between the sensors S1 and S2 are biphasic currents.

In the present application, the biphasic current refers to two phases or pulses of two different intensities, alternating with each other during a treatment. Thus, the currents are shifted in either directions between the sensors 1 and 2.

In other words, it is the function of the magnetic sensors S1 and S2 to sense the changes in the current.

The sensing direction of the sensor S1 in the example is from drive clock A to drive clock B, whereas the sensing direction of a sensor S2 is in the opposite way, from the drive clock B to the drive clock A.

Now, by way of an example, a common mode field shows a direction from drive clock A to drive clock B. As direction does not matter, said common mode field could also go from said drive clock B to said drive clock A.

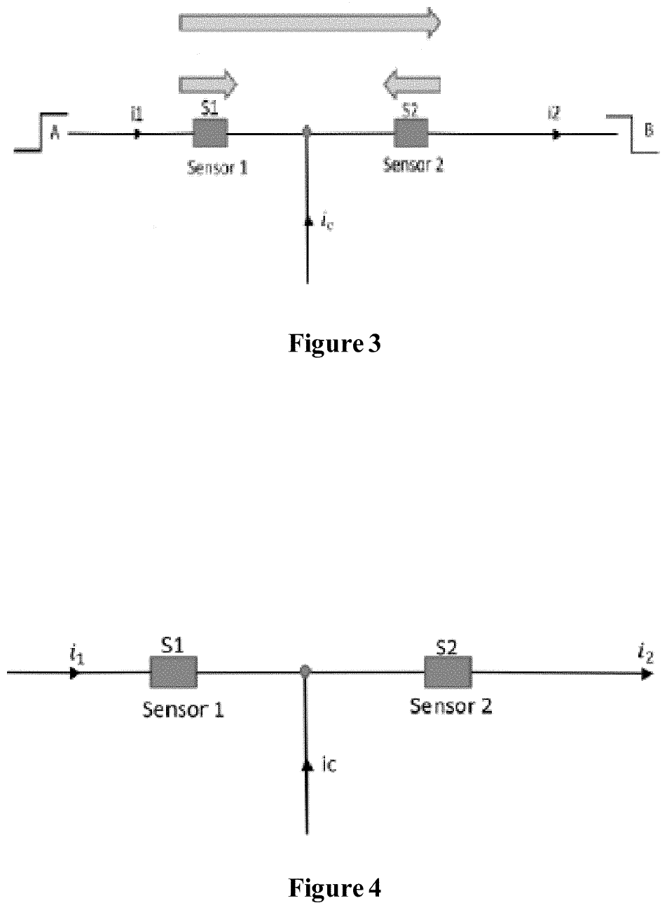

As shown in the FIG. 3, by way of example, when the drive clock A is high and the drive clock B is low, with the current i1 moves from the drive clock A to the drive clock B the common mode field could strengthen the field that is measured with the sensor 1.

In other words, the field is measured, using the sensor S1 is directed in the same direction as the common mode field. According to the FIGS. 1 and 2, both the current and the common mode which is interfering the magnetic fields are in the same direction.

In this case, the sensor S1 is not only measuring the signal field but is also measuring the common mode field.

In other words, the current signal i1 is a function of both the signal field and the interfering field.

In the same example, the current i2 is a function of the signal field of which the interfering field is deducted.

This is due to the opposite directions of both the sensing field of the sensor S1 and the sensor S2.

In other words, when in a phase 2 the currents are reversed, the magnitude and the direction of a correction current is remain the same magnitude and direction, when the sensing field is present and there is no interfering common mode magnetic field.

So, the currents i1 and i2 do not show the signal of the sensors only. The currents and i2 rather show the signal of the sensor and the common mode interfering field added to this signal.

Therefore, a measurement field is corrects the difference between the two sensing field directions i1 and i2.

The signal of the sensor S1 represents the signal of the sensor S1 and the common mode field. Thus, the signal of the sensor S1 represents the current due to the signal field of the sensor S1 and added to it the current due to the common mode field cm1.

Thus, the current i1 comprises the component of the signal of the sensor S1 added to it the component of the common mode interfering field.

Also, with the current of the sensor S2 is the signal of the sensor S2, with the common mode field deducted from the signal of the sensor S2. Which is due to oppositely directed current of the sensor S2 and the common mode field.

According to the invention, one of the sensors S1, S2 is adapted to be a common mode sensor and the respective other sensor S2, S1 is adapted to be a differential mode sensor.

It goes without saying that when the currents i1 and i2 are reversed, the system is oriented the other way round.

So, in the differential mode, is1 represents the measurements which is taken to detect the stress applied to the material.

In other words, the signal is1 is the information which is wanted. However, the signal is1 is interfered by the external common mode field.

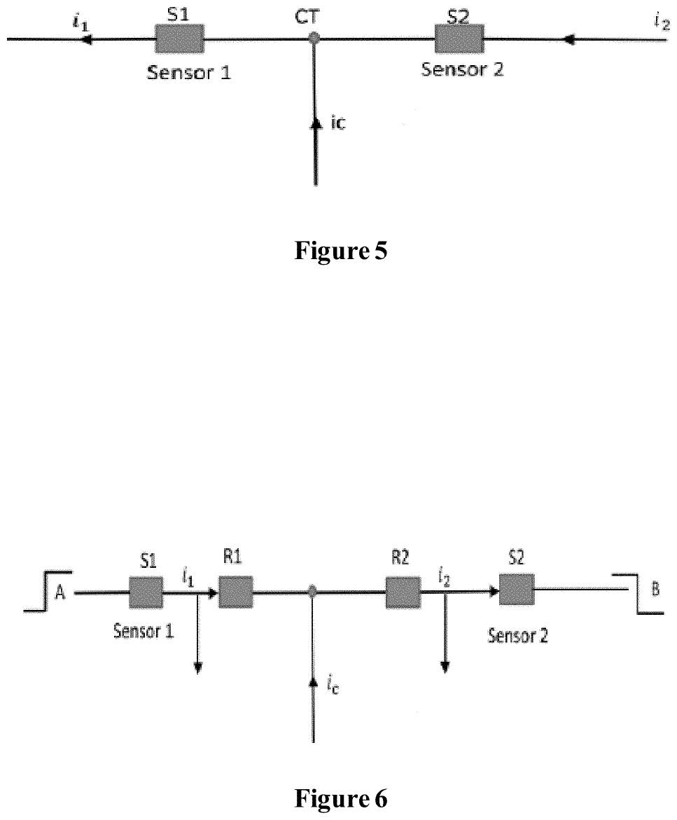

As shown in the FIGS. 4 and 5, the factor which is to be detected by the measurement is the signal is1, which however is interfered by the common mode field cm1.

Thus, the signal i1 in a phase 1 is made up of two components, being the signal is1 and the icm1.

Signals is1 and the icm1 are summed up, what one is left with is the measurement current ic.

It is the measurement current ic, which is used for measuring, with the common mode field disappearing.

Even though the common mode field is present, the common mode field is not visible in the signal ic, when there is a perfect system.

The same applies to the phase 2. Here, the way the currents distribute, the signal ic equals is1 plus icm1, whereas in phase 2 currents distribute as (−is2) plus icm2.

When signals of the phase I and phase II are added together the correction current also remains is =is1 plus is2.

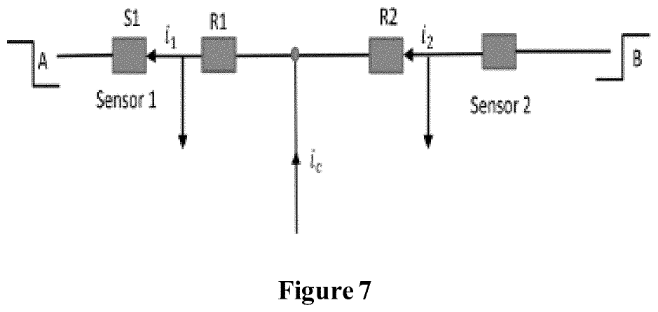

FIG. 6 and FIG. 7 show that even though the currents are bidirectional and even though there is a common mode field present, when the common mode fields are identical, the common mode fields disappear from the measurements.

This is due to the fact that the measurement current IC is made up of the signal (−i1) and the signal (−i2).

The signal of the sensor S2 represents the signal of the sensor S2 and the common mode field.

When the drive clock A is set from 0 V to 5 V level, consequently the drive clock B is set to a 0 V level. This state is called phase 1. In the example according to the FIG. 5, the drive clock A passes from 0 V to 5 V. Consequently, the drive clock B transitions from 5 V to 0 V.

In said phase 1, the currents flow from drive clock A to drive clock B.

As shown in the FIGS. 6 and 7 the system can also be set in an opposite manner. In phase 2 a drive clock A transitions from 5 V to 0 V, whereas the drive clock B is shifted from 0 V to 5 V.

The transition from 5 V to 0 V of the drive clocks A or B depends on a fixed kilohertz-frequency to which the actual drive clock is adjusted.

By way of example, the drive clock A and B is switching from 5 V to 0 V and back to 5 V ad infinitum with a 50% duty cycle and a period of 20 μS, respectively.

As drive clocks A and B are inverted, when the drive clock A is low, then the drive clock B is high and the other way around. Thus, when the drive clock B is low, then the drive clock A is high.

Therefore, the current flows from A to B or B to A for said half period, being 10 μS, respectively.

The invention uses at least one traditional sensor.

Contrary to the sensor of the state-of-the-art, the invention changes the way, the coils of the sensor are connected.

Further, the invention measures the centre tap position arranged between two sensors. In doing this, the presence of the stray fields is detected.

The detection can be done, implementing a single channel, without driving up extra costs.

It is one object of the invention to extract hidden information, as to the magnitude of the external magnetic field, disturbing the signal, issued by the sensors.

It is one purpose of the invention to set up the following four equations.

In the FIG. 7 (phase 1) the drive clock A is set to a value higher than the drive clock B.

Thus there is a current flowing from the drive clock A towards the centre tap CT of i1. Current i2 flows from the centre tap (CT) to the drive clock B.

Therefore, the following formulas apply:

| | |
|---|---|
| A₊ = −iₛ₁ − i_{cm1} | Positive current during A high |
| B₋ = iₛ₂ − i_{cm2} | Negative current during B low |
| B₊ = −iₛ₂ + i_{cm2} | Positive current during B high |
| A₋ = iₛ₁ + i_{cm1} | Negative current during A low |

The values of the signals A+ and B− are added up and combined with added values of the signals B+ and A−.

Then, the difference between the sums of the values of the signals A+ and B− and the sums of the values of B+ and A− are calculated.

What remains is interfering field detection:

IFD=2icm1+2icm2.0

What is claimed is:

1. A method comprising:
detecting an interfering portion of a common mode magnetic field transmitted together with a signal magnetic field each emitted by one of at least two magnetic field sensors (S1; S2),
connecting the magnetic field sensors (S1; S2) in at least one electric circuit, and
with at least two differential drive clocks (A; B) reversing the current flowing in each of the electric circuits.

2. The method according to claim 1, further comprising providing a centre tap (CT) is arranged between the magnetic field sensors (S1; S2).

3. The method according to claim 1, further comprising the following steps:
allocating an electrical component, implementing an electrical resistance (R1; R2) to each of the magnetic field sensors (S1; S2) in the electric circuit,
taking measurements of (A+) and (B−) during an interval of the drive clocks (A; B) switching at a frequency of 10's of KHz, where the drive clock (A) is at a high value and the drive clock (B) is at a low value,
calculating a positive current (A+), flowing through the sensor (S1) by adding up the value of the current (iS1), flowing from the magnetic field sensor (S1) to the electrical component (R1) allocated to the magnetic field sensor (S1) and the current of the common mode field icm1, interfering with the magnetic field sensor (S1),
calculating a negative current (B−), where the drive clock (B) is low, by summing the value of the current (iS2), flowing to the magnetic field sensor (S2) from the electrical component (R2), allocated to the magnetic field sensor (S2) and the current of the common mode field (icm2), interfering with the magnetic field sensor (S2),
taking measurements of (B+) and (A−) during the interval of the drive clock (A; B) switching at a frequency, where the drive clock (B) is at a high value and the drive clock (A) is at a low value,
calculating a positive current (B+), where the drive clock (B) is high, by adding up the value of the current (iS2), flowing from the magnetic field sensor (S2) to the electrical component (R2), allocated to the magnetic field sensor (S2) and the current of the common mode field (icm2), interfering with the magnetic field sensor (S2),
calculating a negative current (A−), flowing through the sensor (S1), by summing up the value of the current (iS1), flowing to the magnetic field sensor (S1) from the electrical component (R1), allocated to the magnetic field sensor (S1) and the current of the common mode field icm1, interfering with the magnetic field sensor (S1),
summing up both the sum of the positive current (A+) and the negative current (B−) and the sum of the positive current (B+) and the negatives current (A−),
calculating the residual interfering field detection (IFD).

4. A device for magnetic field detection, the device comprising at least one electric circuit having differential drive voltages, at least two magnetic field sensors (S1; S2) being connected in the electric circuit, and
emitting at least one signal magnetic field,
wherein at least one electrical component, implementing an electrical resistance (R1; R2) is allocated to each of the magnetic field sensors (S1; S2) in the electric circuit.

5. The device according to claim 4, wherein a centre tap (CT) is arranged between the at least two magnetic field sensors (S1; S2).

6. The device according to claim 4, further comprising at least two drive clocks (A; B), the drive clocks being connected into the electric circuit such that the drive clocks generate the differential drive voltages to reverse the current flowing the electric circuit.

7. The device according to claim 4, wherein the electric circuit is a bi-directional drive.

8. The device according to claim 4, wherein the electrical component implementing an electrical resistance (R1; R2) is a resistor (R1; R2).

9. The device according to claim 4, wherein the device is a bipolar magnetometer.
